(19) United States
(12) Patent Application Publication
(10) Pub. No.: US 2023/0380161 A1
(43) Pub. Date: Nov. 23, 2023

(54) SEMICONDUCTOR MEMORY DEVICE

(71) Applicant: SK hynix Inc., Icheon-si (KR)

(72) Inventor: Nam Kuk KIM, Icheon-si (KR)

(73) Assignee: SK hynix Inc., Icheon-si (KR)

(21) Appl. No.: 17/981,759

(22) Filed: Nov. 7, 2022

(30) Foreign Application Priority Data
May 17, 2022 (KR) 10-2022-0060421

(51) Int. Cl. H01L 27/11582

(52) U.S. Cl. CPC H01L 27/11582

(57) ABSTRACT

A semiconductor memory device includes a stacked structure including insulating layers and conductive layers that are alternately disposed in a vertical direction, a first structure including a channel layer that passes through the stacked structure and a memory pattern between the channel layer and the stacked structure, and a second structure including an insulating pattern that is formed along a sidewall of the stacked structure and a gate pattern that is formed on a sidewall of the insulating pattern.

### CROSS-REFERENCE TO RELATED APPLICATION

The present application claims priority under 35 U.S.C. § 119(a) to Korean patent application number 10-2022-0060421, filed on May 17, 2022, in the Korean Intellectual Property Office, the entire disclosure of which is incorporated herein by reference.

### BACKGROUND

### 1. Technical Field

Various embodiments of the present disclosure generally relate to a semiconductor memory device, and more particularly, to a three-dimensional semiconductor memory device.

### 2. Related Art

Non-volatile memory devices retain stored data even in the absence of supplied power. Due to the limitations in increasing integration density of two-dimensional non-volatile memory devices in which memory cells are formed in a single layer over a substrate, three-dimensional non-volatile memory devices have been proposed in which memory cells are stacked in a vertical direction over a substrate.

Three-dimensional non-volatile memory devices may include insulating layers and gate electrodes alternately stacked on each other and channel layers passing through the insulating layers and the gate electrodes, and memory cells may be stacked along the channel layers. Various structures and manufacturing methods have been developed to improve the operational reliability of the three-dimensional non-volatile memory devices having the above-described configuration.

### SUMMARY

According to an embodiment of the present disclosure, a semiconductor memory device may include a stacked structure including insulating layers and conductive layers that are alternately disposed in a vertical direction, a first structure including a channel layer that passes through the stacked structure and a memory pattern between the channel layer and the stacked structure, and a second structure including an insulating pattern that is formed along a sidewall of the stacked structure and a gate pattern that is formed on a sidewall of the insulating pattern.

According to an embodiment of the present disclosure, a semiconductor memory device may include a first stacked structure and a second stacked structure that are spaced apart from each other, wherein each of the first and second stacked structures includes conductive layers that are stacked in a vertical direction, a first structure including a first channel pattern that passes through the conductive layers of the first stacked structure and a first memory pattern between the first channel pattern and the first stacked structure, a second structure disposed between the first stacked structure and the second stacked structure, and a third structure including a second channel pattern that passes through the conductive layers of the second stacked structure and a second memory pattern between the second channel pattern and the second stacked structure, wherein the second structure includes a gate pattern between the first structure and the third structure, and wherein the second structure includes insulating patterns at opposite sides of the gate pattern.

According to an embodiment of the present disclosure, a semiconductor memory device may include a stacked structure including insulating layers and conductive layers that are alternately disposed in a vertical direction, a first structure including a first channel pattern that passes through the stacked structure and a first memory pattern between the first channel pattern and the stacked structure, second structures passing through the stacked structure and neighboring each other with the first structure interposed therebetween, and a third structure facing the first structure between the second structures and including a second channel pattern that passes through the stacked structure and a second memory pattern between the second channel pattern and the stacked structure, wherein each of the second structures includes an insulating pattern that is formed along a sidewall of the stacked structure, and wherein each of the second structures includes a gate pattern that is formed on a sidewall of the insulating pattern.

### BRIEF DESCRIPTION OF THE DRAWINGS

FIG. 1 is a block diagram illustrating a semiconductor memory device according to an embodiment;

FIG. 2A is a plan view of a semiconductor memory device according to an embodiment and FIG. 2B is an enlarged plan view of region A of FIG. 2A;

FIG. 3A is a plan view of a semiconductor memory device according to an embodiment and FIG. 3B is an enlarged plan view of region B of FIG. 3A;

FIGS. 4A and 4B are plan views of a semiconductor memory device according to an embodiment, and more specifically, FIG. 4B is an enlarged plan view of region C of FIG. 4A;

FIGS. 5A, 5B, 5C, and 5D are cross-sectional diagrams illustrating a method of manufacturing a semiconductor memory device according to an embodiment shown in FIGS. 2A and 2B;

FIGS. 6A and 6B are cross-sectional diagrams illustrating a method of manufacturing a semiconductor memory device according to an embodiment shown in FIGS. 3A and 3B;

FIG. 7 is a block diagram illustrating a configuration of a memory system according to an embodiment; and

FIG. 8 is a block diagram illustrating a configuration of a computing system according to an embodiment.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. It will be understood that although the terms first, second, third etc. may be used herein to describe various elements, these elements should not be limited by these terms. These terms are only used to distinguish one element from another element, but not used to define only the element itself or to mean a particular sequence.

Various embodiments are directed to a semiconductor memory device capable of improving operational reliability thereof.

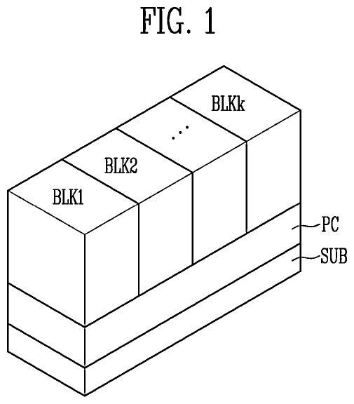

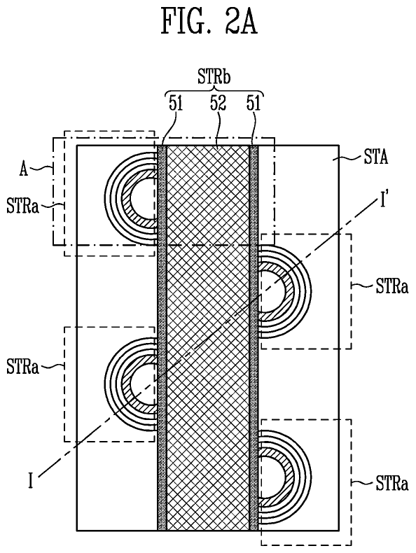

FIG. 1 is a block diagram illustrating a semiconductor memory device according to an embodiment.

Referring to FIG. 1, the semiconductor memory device may include a peripheral circuit structure PC and memory blocks BLK1 to BLKk that are disposed over a substrate SUB, where k is a natural number of 2 or more. The memory blocks BLK1 to BLKk may overlap with the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed by a selective epitaxial growth method.

The peripheral circuit structure PC may include a row decoder, a column decoder, a page buffer, and a control circuit that form a circuit for controlling the operation of the memory blocks BLK1 to BLKk. For example, the peripheral circuit structure PC may include an NMOS transistor, a PMOS transistor, a resistor, and a capacitor that are electrically coupled to the memory blocks BLK1 to BLKk. The peripheral circuit structure PC may be disposed between the substrate SUB and the memory blocks BLK1 to BLKk. However, the present disclosure does not exclude an embodiment in which the peripheral circuit structure PC extends to a region of the substrate SUB which does not overlap with the memory blocks BLK1 and BLKk.

Each of the memory blocks BLK1 to BLKk may include impurity-doped regions, bit lines, cell strings electrically coupled to the impurity-doped regions and the bit lines, word lines electrically coupled to the cell strings, and select lines electrically coupled to the cell strings. Each of the cell strings may include memory cells and select transistors that are coupled in series to each other by a channel structure. Each of the select lines may serve as a gate electrode of a corresponding one of the select transistors. Each of the word lines may serve as a gate electrode of a corresponding one of the memory cells.

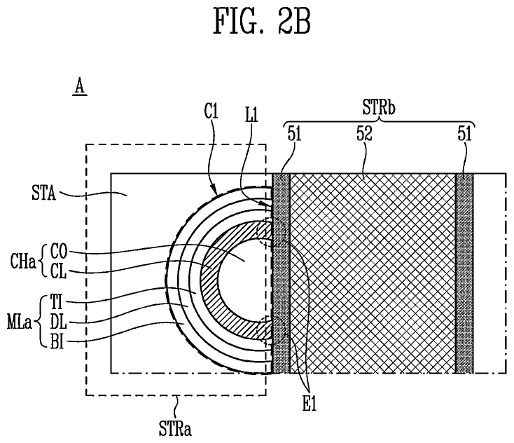

FIG. 2A is a plan view of a semiconductor memory device according to an embodiment and FIG. 2B is an enlarged plan view of region A of FIG. 2A.

Referring to FIGS. 2A and 2B, the semiconductor memory device may include a stacked structure STA, first structures STRa, and a second structure STRb.

The stacked structure STA may include a plurality of layers that are stacked over the substrate SUB shown in FIG. 1. For example, the stacked structure STA may include insulating layers and conductive layers that are alternately stacked over the substrate SUB shown in FIG. 1.

The first structures STRa may extend in a vertical direction to pass through the stacked structure STA. The vertical direction may be defined as a direction in which the insulating layers and the conductive layers of the stacked structure STA are stacked. Each of the first structures STRa may include a first channel pattern CHa and a first memory pattern MLa.

The first channel pattern CHa may include a channel layer CL and a core pillar CO. The channel layer CL and the core pillar CO may extend in the vertical direction to pass through the stacked structure STA. The channel layer CL and the core pillar CO may contact the second structure STRb. The channel layer CL may include a semiconductor material that can be used as a channel region. The core pillar CO may include an insulating material.

The first memory pattern MLa may include a tunnel insulating layer TI formed on a sidewall of the channel layer CL, a data storage layer DL formed on a sidewall of the tunnel insulating layer TI, and a blocking insulating layer BI formed on a sidewall of the data storage layer DL. The data storage layer DL may include a material layer capable of storing data changed by using Fowler-Nordheim tunneling. The data storage layer DL may include various materials, for example, a charge trap layer. The charge trap layer may include a nitride layer. However, embodiments of the present disclosure are not limited thereto, and the data storage layer DL may include a phase-change material, nanodots, or the like. The blocking insulating layer BI may include an oxide layer capable of blocking charges. The tunnel insulating layer TI may include a silicon oxide layer enabling charge tunneling.

The second structure STRb may contact the first structures STRa. The second structure STRb may extend in the vertical direction. The second structure STRb may include an insulating pattern 51 and a gate pattern 52. The insulating pattern 51 may be disposed as a sidewall of the second structure STRb and the gate pattern 52 may be disposed in a central region of the second structure STRb. The insulating pattern 51 and the gate pattern 52 may extend in the vertical direction.

The insulating pattern 51 may extend along a sidewall of the gate pattern 52. The insulating pattern 51 may be disposed between the first structures STRa and the gate pattern 52 and may extend between the stacked structure STA and the gate pattern 52. The insulating pattern 51 may include at least one of an oxide and a nitride. According to an embodiment, the insulating pattern 51 may be a single layer disposed between the first structures STRa and the gate pattern 52 and including an oxide. According to another embodiment, the insulating pattern 51 may be a triple layer disposed between the first structures STRa and the gate pattern 52 and including a first oxide, a nitride, and a second oxide.

The gate pattern 52 may be spaced apart from the channel layer CL of the first structure STRa by the insulating pattern 51. In an embodiment, according to an electrical signal applied to the gate pattern 52, a leakage current from the channel layer CL which is induced by a shape of the first structure STRa may be controlled.

The first structures STRa may be disposed at opposite sides of the second structure STRb and may be spaced apart from each other. The first structures STRa may be arranged in a zigzag pattern. However, embodiments of the present disclosure are not limited thereto. For example, the first structures STRa may be symmetrically arranged to each other with respect to the second structure STRb.

The first structure STRa may include a first curved portion C1 and a first straight portion L1. According to an embodiment, the first structure STRa may have substantially a semicircular shape in a plan view. The first straight portion L1 of the first structure STRa may contact the second structure STRb. The first straight portion L1 of the first structure STRa may contact the insulating pattern 51 of the second structure STRb. The first curved portion C1 of the first structure STRa may contact the stacked structure STA.

In an embodiment, the first memory pattern MLa disposed between the channel layer CL and each of the conductive layers of the stacked structure STA may serve as a memory cell. In an embodiment, when an electric field is formed in the channel layer CL by a voltage applied to the conductive layers of the stacked structure STA, the electric field may be concentrated in edges (E1) of the channel layer CL which are formed at intersections of the first straight portion L1 and the first curved portion C1. Accordingly, in an embodiment, a leakage current may occur in the edges (E1) of the channel layer CL. In an embodiment, the leakage current may be controlled by a voltage applied to the gate pattern 52. In other words, in an embodiment, a current of the channel layer CL may be elaborately controlled by the gate pattern 52.

The second structure STRb may extend in a horizontal direction parallel to each of the insulating layers and the conductive layers of the stacked structure STA. According to an embodiment, the second structure STRb may have a linear shape extending in the horizontal direction in a plan view.

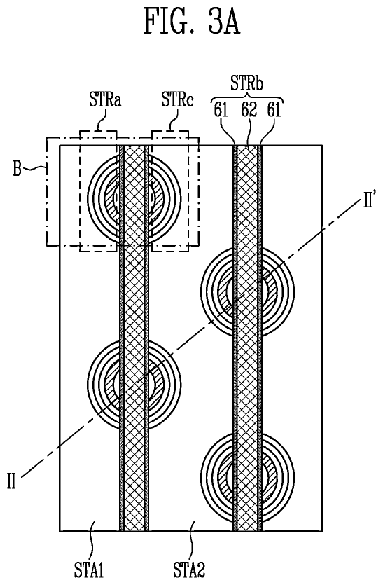

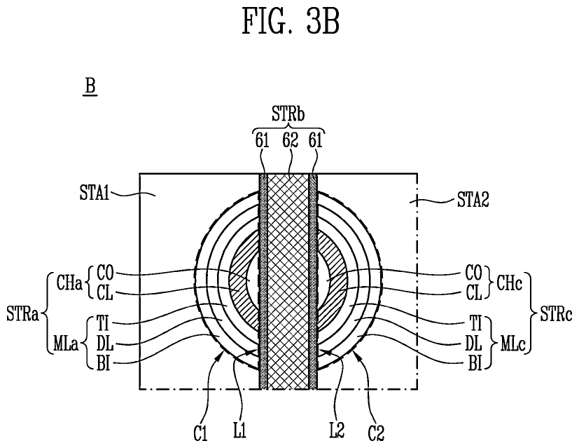

FIG. 3A is a plan view of a semiconductor memory device according to an embodiment and FIG. 3B is an enlarged plan view of region B of FIG. 3A. Hereinafter, any repetitive detailed description of components already mentioned above with reference to FIGS. 2A and 2B will be omitted for the sake of brevity.

Referring to FIGS. 3A and 3B, the semiconductor memory device may include first stacked structures STA1, a second stacked structure STA2, the first structures STRa, the second structures STRb, and third structures STRc. Each of the first stacked structure STA1 and the second stacked structure STA2 may include a plurality of insulating layers and a plurality of conductive layers that are alternately stacked over the substrate SUB shown in FIG. 1. The plurality of insulating layers and the plurality of conductive layers may be alternately disposed in a vertical direction that intersects a top surface of the substrate SUB shown in FIG. 1.

The second structure STRb may be disposed between the first stacked structure STA1 and the second stacked structure STA2. The first stacked structure STA1 and the second stacked structure STA2 may be separated from each other by the second structure STRb.

The first structure STRa may extend in the vertical direction to pass through the plurality of insulating layers and the plurality of conductive layers of the first stacked structure STA1. The third structure STRc may extend in the vertical direction to pass through the plurality of insulating layers and the plurality of conductive layers of the second stacked structure STA2. The first structure STRa and the third structure STRc may be separated from each other by the second structure STRb. The first structure STRa and the third structure STRc may be respectively disposed at opposite sides of the second structure STRb. According to an embodiment, the first structure STRa and the third structure STRc may be symmetrical with respect to the second structure STRb. The second structure STRb may contact the first structure STRa. The third structure STRc may contact the second structure STRb.

The first structure STRa may include the first curved portion C1 and the first straight portion L1. The first straight portion L1 may contact the second structure STRb. The first curved portion C1 may extend along a sidewall of the first stacked structure STA1 from the first straight portion L1. The first curved portion C1 may contact the first stacked structure STA1.

The third structure STRc may include a second curved portion C2 and a second straight portion L2. The second straight portion L2 may contact the second structure STRb. The second curved portion C2 may extend along a sidewall of the second stacked structure STA2 from the second straight portion L2. The second curved portion C2 may contact the second stacked structure STA2.

The first structure STRa may include the first channel pattern CHa and the first memory pattern MLa. The first channel pattern CHa may include the channel layer CL and the core pillar CO. The first memory pattern MLa may include the tunnel insulating layer TI formed on the sidewall of the channel layer CL, the data storage layer DL formed on the sidewall of the tunnel insulating layer TI, and the blocking insulating layer BI formed on the sidewall of the data storage layer DL. The first channel pattern CHa and the first memory pattern MLa described with reference to FIGS. 3A and 3B may include the same materials as the first channel pattern CHa and the first memory pattern MLa, respectively, which are described above with reference to FIGS. 2A and 2B.

The third structure STRc may include a second channel pattern CHc and a second memory pattern MLc. The second channel pattern CHc may include the channel layer CL and the core pillar CO. The second memory pattern MLc may include the tunnel insulating layer TI formed on the sidewall of the channel layer CL, the data storage layer DL formed on the sidewall of the tunnel insulating layer TI, and the blocking insulating layer BI formed on the sidewall of the data storage layer DL. The second channel pattern CHc and the second memory pattern MLc described with reference to FIGS. 3A and 3B may include the same materials as the first channel pattern CHa and the first memory pattern MLa, respectively, which are described above with reference to FIGS. 2A and 2B.

The second structure STRb may include an insulating pattern 61 and a gate pattern 62. Materials that are included in the insulating pattern 61 and the gate pattern 62 may be the same as those in the insulating pattern 51 and the gate pattern 52, respectively, which are described above with reference to FIGS. 2A and 2B. The gate pattern 62 may extend in the vertical direction.

In an embodiment, the first memory pattern MLa disposed between the channel layer CL of the first structure STRa and each of the conductive layers of the first stacked structure STA1 may serve as a memory cell. Also, in an embodiment, the second memory pattern MLc disposed between the channel layer CL of the third structure STRc and each of the conductive layers of the second stacked structure STA2 may serve as a memory cell. In an embodiment, when an electric field is formed in the channel layer CL of the first channel pattern CHa by a voltage applied to the conductive layers of the first stacked structure STA1, the electric field may be concentrated in edges of the channel layer CL which are formed at intersections of the first curved portion C1 and the first straight portion L1, and therefore, a leakage current may occur in the edges of the channel layer CL. In an embodiment, when an electric field is formed in the channel layer CL of the second channel pattern CHc by a voltage applied to the conductive layers of the second stacked structure STA2, the electric field may be concentrated in edges of the channel layer CL which are formed at intersections of the second curved portion C2 and the second straight portion L2, and therefore, a leakage current may occur in the edges of the channel layer CL. The above-described leakage current, in an embodiment, may be elaborately controlled by a voltage applied to the gate pattern 62.

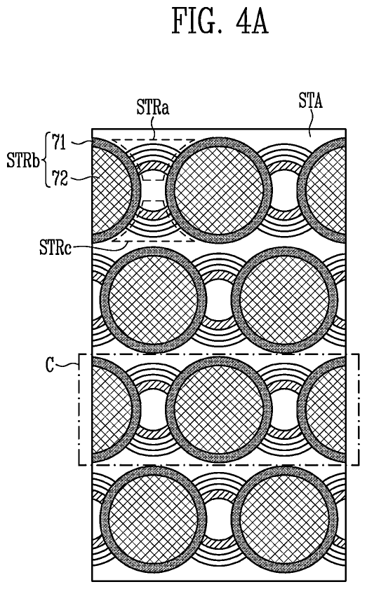

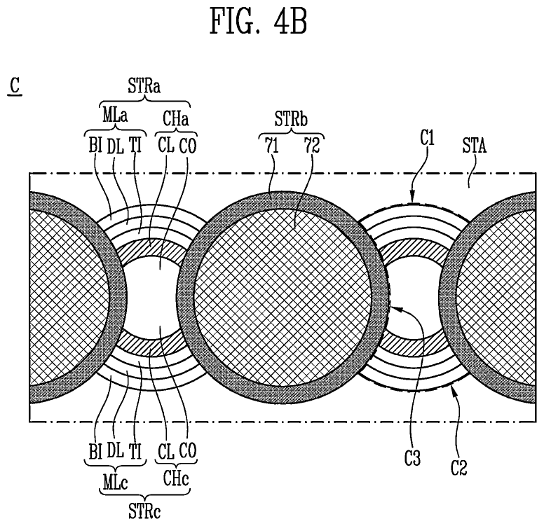

FIGS. 4A and 4B are plan views of a semiconductor memory device according to an embodiment, and more specifically, FIG. 4B is an enlarged plan view of region C of FIG. 4A.

Referring to FIGS. 4A and 4B, the semiconductor memory device may include the stacked structure STA, the first structures STRa, the second structures STRb, and the third structures STRc. The stacked structure STA may include a plurality of layers that are stacked over the substrate SUB shown in FIG. 1. For example, the stacked structure STA may include insulating layers and conductive layers that are alternately stacked over the substrate SUB shown in FIG. 1.

The first structures STRa may extend in a vertical direction to pass through the stacked structure STA. Each of the first structures STRa may include the first channel pattern CHa and the first memory pattern MLa. The third structures STRc may extend in the vertical direction to pass through the insulating layers and the conductive layers of the stacked structure STA. A pair of the first structure STRa and the third structure STRc may correspond to and may be disposed between the second structures STRb that neighbor each other in one direction such that the first structure STRa and the third structure STRc face each other. According to an embodiment, the first structure STRa and the third structure STRc between the second structures STRb may be symmetrical. The second structure STRb may contact the first structure STRa. The third structure STRc may contact the second structure STRb. The first memory pattern MLa of the first structure STRa and the second memory pattern MLc of the third structure STRc that face each other may be separated from each other by the second structure STRb.

The first structure STRa may include the first curved portion C1. The first curved portion C1 may extend along a sidewall of the stacked structure STA. The first curved portion C1 may contact the stacked structure STA.

The third structure STRc may include the second curved portion C2. The second curved portion C2 may extend along the sidewall of the stacked structure STA. The second curved portion C2 may contact the stacked structure STA.

The first structure STRa may include the first channel pattern CHa and the first memory pattern MLa. The first channel pattern CHa may include the channel layer CL and the core pillar CO. The first memory pattern MLa may include the tunnel insulating layer TI formed on the sidewall of the channel layer CL, the data storage layer DL formed on the sidewall of the tunnel insulating layer TI, and the blocking insulating layer BI formed on the sidewall of the data storage layer DL. The first channel pattern CHa and the first memory pattern MLa described with reference to FIGS. 4A and 4B may include the same materials as the first channel pattern CHa and the first memory pattern MLa, respectively, which are described above with reference to FIGS. 2A and 2B.

The third structure STRc may include the second channel pattern CHc and the second memory pattern MLc. The second channel pattern CHc may include the channel layer CL and the core pillar CO. The second memory pattern MLc may include the tunnel insulating layer TI formed on the sidewall of the channel layer CL, the data storage layer DL formed on the sidewall of the tunnel insulating layer TI, and the blocking insulating layer BI formed on the sidewall of the data storage layer DL. The second channel pattern CHc and the second memory pattern MLc described with reference to FIGS. 4A and 4B may include the same materials as the first channel pattern CHa and the first memory pattern MLa, respectively, which are described above with reference to FIGS. 2A and 2B.

The second structure STRb may include an insulating pattern 71 and a gate pattern 72. Materials included in the insulating pattern 71 and the gate pattern 72 may be the same as those in the insulating pattern 51 and the gate pattern 52 described above with reference to FIGS. 2A and 2B. The gate pattern 72 may extend in the vertical direction.

The second structure STRb may include a third curved portion C3. The third curved portion C3 may contact the first structure STRa and the third structure STRc. For example, the second structure STRb may have substantially a cylindrical shape.

The channel layer CL of the first structure STRa and the channel layer CL of the third structure STRc that face each other may be separated from each other by the second structure STRb.

In an embodiment, the first memory pattern MLa which is disposed between the channel layer CL of the first structure STRa and each of the conductive layers of the stacked structure STA and the second memory pattern MLc which is disposed between the channel layer CL of the third structure STRc and each of the conductive layers of the stacked structure STA may serve as memory cells. In an embodiment, when an electric field is formed in the channel layer CL of the first channel pattern CHa by a voltage applied to the conductive layer of the stacked structure STA, the electric field may be concentrated in edges of the channel layer CL which are formed at intersections of the first curved portion C1 and the third curved portion C3. Therefore, in an embodiment, a leakage current may occur in the edges of the channel layer CL. Similarly, in an embodiment, when an electric field is formed in the channel layer CL of the second channel pattern CHc by a voltage applied to the conductive layer of the stacked structure STA, the electric field may be concentrated in edges of the channel layer CL which are formed at intersections of the second curved portion C2 and the third curved portion C3. Therefore, in an embodiment, a leakage current may occur in the edges of the channel layer CL. The above-described leakage current, in an embodiment, may be elaborately controlled by a voltage applied to the gate pattern 72.

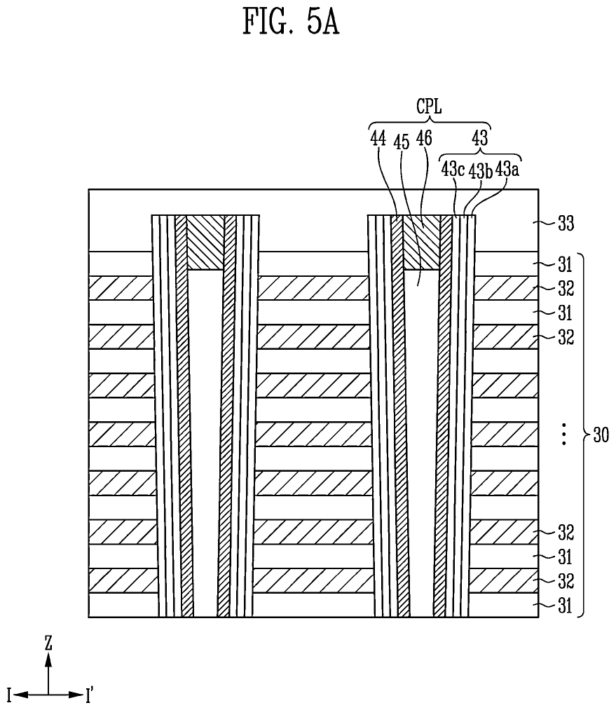

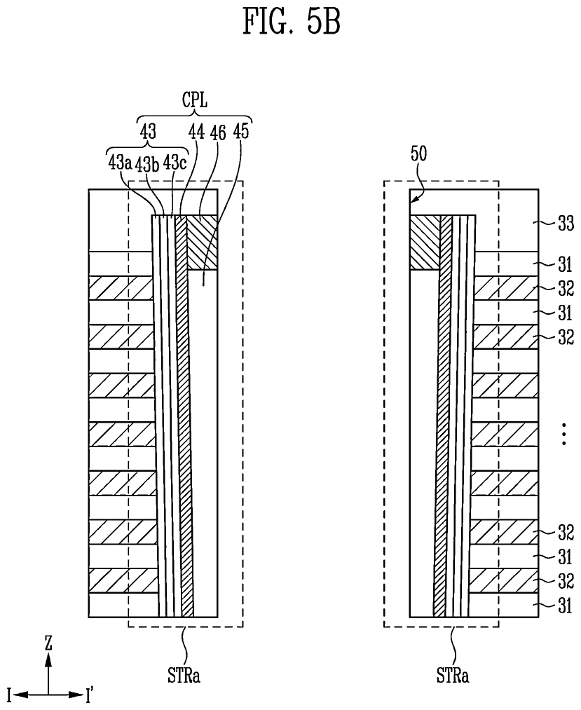

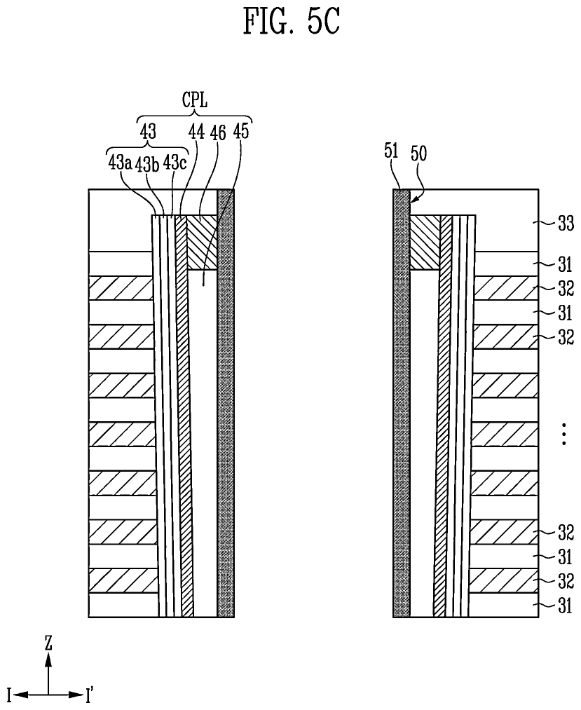

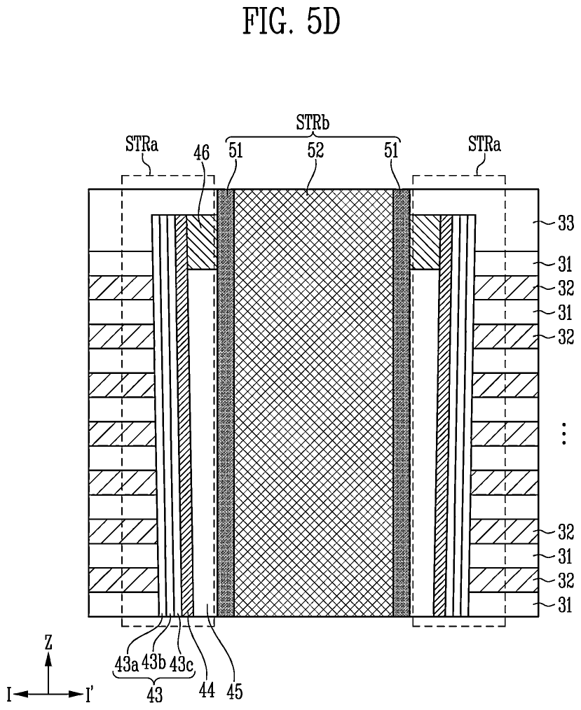

FIGS. 5A to 5D are cross-sectional diagrams illustrating a method of manufacturing a semiconductor memory device according to an embodiment shown in FIGS. 2A and 2B. Each of FIGS. 5A to 5D illustrates a cross-sectional diagram taken along line I-I′ of FIG. 2A.

Referring to FIG. 5A, a preliminary stacked structure may be formed by alternately stacking a plurality of first material layers 31 and a plurality of second material layers 32 in a vertical direction Z. The first material layer 31 may be an insulating layer. The first material layer 31 may include various insulating materials. According to an embodiment, the first material layer 31 may include an oxide. The second material layer 32 may include at least one of a doped silicon layer, a metal silicide layer, tungsten, nickel, and cobalt.

Cell plugs CPL passing through the plurality of first material layers 31 and the plurality of second material layers 32 may be formed. Each of the cell plugs CPL may include a memory layer 43 formed on a sidewall of a hole that passes through the preliminary stacked structure 30, a channel layer 44 on the memory layer 43, and a core pillar 45 and a capping pattern 46 that fill a central region of the hole. The capping pattern 46 may be disposed on the core pillar 45.

The memory layer 43 may include a tunnel insulating layer 43c formed on a sidewall of the channel layer 44, a data storage layer 43b formed on a sidewall of the tunnel insulating layer 43c, and a blocking insulating layer 43a formed on a sidewall of a data storage layer 43b. The channel layer 44 may include a semiconductor material and serve as a channel region of a memory cell string. According to an embodiment, the channel layer 44 may include silicon, germanium, or a combination thereof. The capping pattern 46 may include a semiconductor material including a conductive dopant for a junction. According to an embodiment, the capping pattern 46 may include silicon, germanium, or a combination thereof. According to an embodiment, the capping pattern 46 may include n-type doped silicon.

An upper insulating layer 33 covering the cell plugs CPL and the preliminary stacked structure 30 may be formed. According to an embodiment, the upper insulating layer 33 may include an oxide.

Referring to FIG. 5B, a trench 50 passing through the cell plugs CPL may be formed. The trench 50 may pass through the preliminary stacked structure 30 shown in FIG. 5A between the cell plugs CPL.

The plurality of first material layers 31 and the plurality of second material layers 32 may be divided into the stacked structures STA shown in FIGS. 2A and 2B by the trench 50. The first material layers 31 in each of the stacked structures STA may serve as the insulating layers among the plurality of layers that are described above with reference to FIGS. 2A and 2B. The second material layers 32 in each of the stacked structures STA may serve as the conductive layers among the plurality of layers that are described above with reference to FIGS. 2A and 2B.

A part of each of the cell plugs CPL may be removed when the trench 50 is formed. A remaining part of each of the cell plugs CPL may form the first structure STRa shown in FIGS. 2A and 2B. The first straight portion L1 of the first structure STRa shown in FIGS. 2A and 2B may form a sidewall of the cell plug CPL which is formed along the trench 50 shown in FIG. 5B. The first curved portion C1 of the first structure STRa shown in FIGS. 2A and 2B may form a sidewall of the cell plug CPL which contacts the plurality of first material layers 31 and the plurality of second material layers 32 shown in FIG. 5B.

Referring to FIG. 5C, the insulating pattern 51 may be formed along a sidewall of the trench 50. The insulating pattern 51 may include at least one of an oxide and a nitride. According to an embodiment, the insulating pattern 51 may include a single layer of an oxide. According to another embodiment, the insulating pattern 51 may include a triple layer of a first oxide, a nitride, and a second oxide, and more particularly, the first oxide formed along the sidewall of the trench 50, the nitride formed along a sidewall of the first oxide, and the second oxide formed along a sidewall of the nitride.

Referring to FIG. 5D, the gate pattern 52 may be formed along a sidewall of the insulating pattern 51. The gate pattern 52 may be disposed in the trench 50. According to an embodiment, the gate pattern 52 may fill a central region of the trench 50 which is not filled with the insulating pattern 51. Accordingly, the second structure STRb may be formed. FIG. 5D merely illustrates a part of the channel layer 44 which corresponds to the first curved portion C1 of the first structure STRa shown in FIG. 2B. However, the channel layer 44 may have edges (E1) disposed at intersections of the first curved portion C1 and the first straight portion L1 as shown in FIG. 2B. In an embodiment, a leakage current that is more likely to occur at the edges (E1) of the channel layer 44 may be controlled by the gate pattern 52 as described above with reference to FIGS. 2A and 2B.

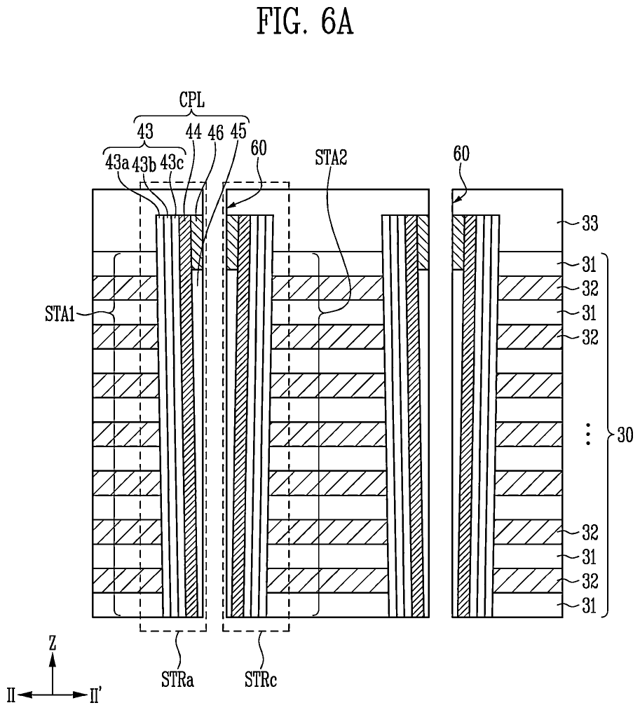

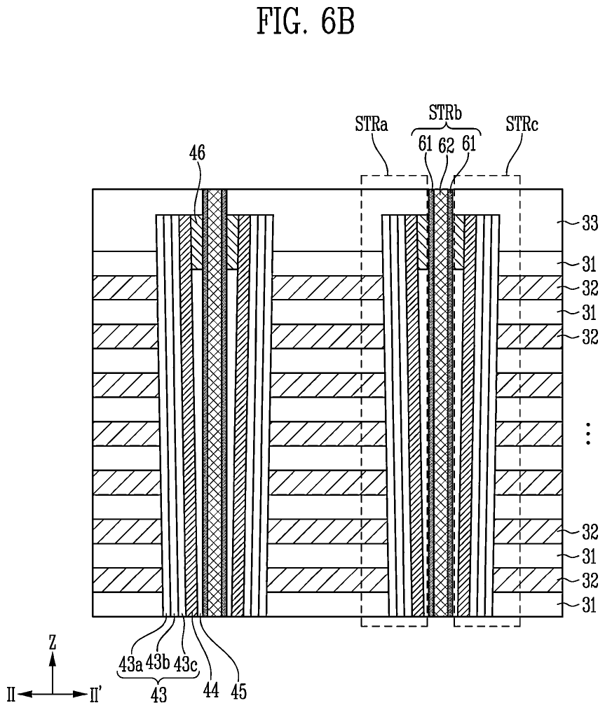

FIGS. 6A and 6B are cross-sectional diagrams illustrating a method of manufacturing a semiconductor memory device according to an embodiment shown in FIGS. 3A and 3B. Each of FIGS. 6A and 6B illustrates a cross-sectional diagram taken along line II-II′ of FIG. 3A.

Referring to FIG. 6A, the preliminary stacked structure 30 including the plurality of first material layers 31 and the plurality of second material layers 32 and the cell plugs CPL passing through the preliminary stacked structure 30 may be formed. The plurality of first material layers 31 may be insulating layers and the plurality of second material layers 32 may be conductive layers.

The cell plugs CPL and the preliminary stacked structure 30 may be covered by the upper insulating layer 33. Each of the cell plugs CPL may include the memory layer 43 on a sidewall of a hole that passes through the preliminary stacked structure 30, the channel layer 44 on the memory layer 43, and the core pillar 45 and the capping pattern 46 that fill a central region of the hole. The capping pattern 46 may be disposed on the core pillar 45.

A trench 60 passing through the core pillar 45 and the capping pattern 46 of each of the cell plugs CPL may be formed. Each of the cell plugs CPL may be divided into the first structure STRa and the third structure STRc described above with reference to FIGS. 3A and 3B by the trench 60.

The plurality of first material layers 31 and the plurality of second material layers 32 may be divided into the plurality of stacked structures STA1 and STA2 by the trench 60. The plurality of stacked structures STA1 and STA2 may include the first stacked structure STA1 and the second stacked structure STA2 that are respectively disposed at opposite sides of the trench 60. The first stacked structure STA1 may include the plurality of first material layers 31 and the plurality of second material layers 32 alternately disposed in the vertical direction Z along a sidewall of the first structure STRa. The second stacked structure STA2 may include the plurality of first material layers 31 and the plurality of second material layers 32 alternately disposed in the vertical direction Z along a sidewall of the third structure STRc. Each of the first straight portion L1 of the first structure STRa and the second straight portion L2 of the third structure STRc shown in FIGS. 3A and 3B may form a sidewall of the cell plug CPL which is formed along the trench 60 shown in FIG. 6A. Each of the first curved portion C1 of the first structure STRa and the second curved portion C2 of the third structure STRc shown in FIGS. 3A and 3B may form a sidewall of the cell plug CPL which contacts the plurality of first material layers 31 and the plurality of second material layers 32 shown in FIG. 6A.

Referring to FIG. 6B, the insulating pattern 61 may be formed along the sidewall of the trench 60. The insulating pattern 61 may include at least one of an oxide and a nitride. Subsequently, the gate pattern 62 may be formed along the sidewall of the insulating pattern 61. The gate pattern 62 may be formed in the trench 60. Accordingly, the second structure STRb may be formed. FIG. 6B merely illustrates parts of the channel layer 44 which correspond to the first curved portion C1 of the first structure STRa and the second curved portion C2 of the third structure STRc shown in FIG. 3B. However, the channel layer 44 may have edges disposed at intersections of the first curved portion C1 and the first straight portion L1 and edges disposed at intersections of the second curved portion C2 and the second straight portion L2 as shown in FIG. 3B. In an embodiment, a leakage current that is more likely to occur at the edges of the channel layer 44 may be controlled by the gate pattern 62 as described above with reference to FIGS. 3A and 3B.

Forming the semiconductor memory device shown in FIGS. 4A and 4B may include forming a plurality of cell plugs that pass through a preliminary stacked structure and forming a plurality of gate holes that pass through the preliminary stacked structure. The preliminary stacked structure and the plurality of cell plugs may be formed using processes described above with reference to FIGS. 5A and 6A. In a planar viewpoint, the plurality of gate holes may be disposed alternately with and may contact the plurality of cell plugs. Accordingly, the preliminary stacked structure may be divided into the stacked structures STA as shown in FIGS. 4A and 4B. Subsequently, as shown in FIGS. 4A and 4B, the second structure STRb may be provided by forming the insulating pattern 71 and the gate pattern 72 described above with reference to FIGS. 4A and 4B in each of the plurality of gate holes.

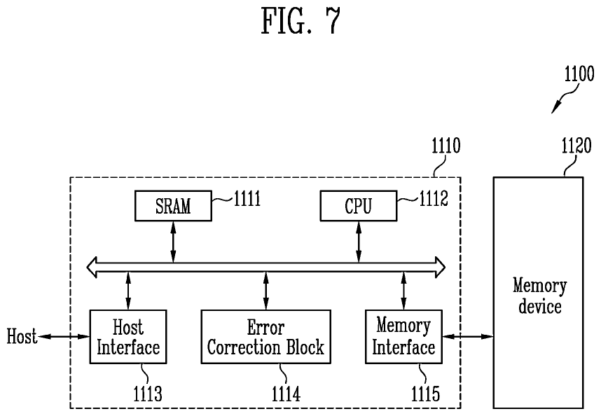

FIG. 7 is a block diagram illustrating a configuration of a memory system 1100 according to an embodiment.

Referring to FIG. 7, the memory system 1100 may include a memory device 1120 and a memory controller 1110.

The memory device 1120 may be a multi-chip package including a plurality of flash memory chips.

The memory controller 1110 may be configured to control the memory device 1120 and may include Static Random Access Memory (SRAM) 1111, a Central Processing Unit (CPU) 1112, a host interface 1113, an error correction block 1114, and a memory interface 1115. The SRAM 1111 may serve as operating memory of the CPU 1112, the CPU 1112 may perform general control operations for data exchange of the memory controller 1110, and the host interface 1113 may include a data exchange protocol of a host accessing the memory system 1100. The error correction block 1114 may detect and correct an error included in data read from the memory device 1120. The memory interface 1115 may interface with the memory device 1120. The memory controller 1110 may further include Read Only Memory (ROM) for storing code data for interfacing with the host.

The memory system 1100 having the above-described configuration may be a Solid-State Drive (SSD) or a memory card in which the memory device 1120 and the memory controller 1110 are combined. For example, when the memory system 1100 is an SSD, the memory controller 1110 may communicate with an external device (e.g., a host) through one of various interface protocols such as a Universal Serial Bus (USB) protocol, a MultiMedia Card (MMC) protocol, a Peripheral Component Interconnect Express (PCIe) protocol, a Serial Advanced Technology Attachment (SATA) protocol, a Parallel Advanced Technology Attachment (PATA) protocol, a Small Computer System Interface (SCSI) protocol, an Enhanced Small Disk Interface (ESDI) protocol, and an Integrated Drive Electronics (IDE) protocol.

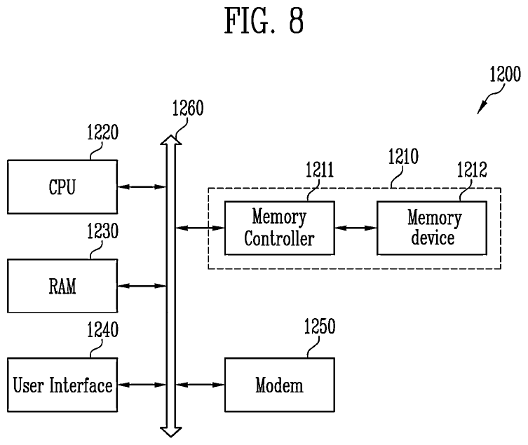

FIG. 8 is a block diagram illustrating a configuration of a computing system 1200 according to an embodiment.

Referring to FIG. 8, the computing system 1200 may include a CPU 1220, Random Access Memory (RAM) 1230, a user interface 1240, a modem 1250, and a memory system 1210 that are electrically coupled to a system bus 1260. When the computing system 1200 is a mobile device, a battery for supplying an operating voltage to the computing system 1200 may be further included, and an application chipset, an image processor, mobile DRAM, and the like may be further included.

The memory system 1210 may include a memory device 1212 and a memory controller 1211.

The memory controller 1211 may be configured in the same manner as the memory controller 1110 described above with reference to FIG. 7.

According to various embodiments of the present disclosure, integration density of memory cells may be improved by separating structures from each other and a leakage current may be controlled by forming a gate pattern in a region that separates the structures from each other. Accordingly, according to various embodiments of the present disclosure, because the leakage current may be controlled, operational reliability of a semiconductor memory device may be improved.

What is claimed is:

1. A semiconductor memory device, comprising:
a stacked structure including insulating layers and conductive layers that are alternately disposed in a vertical direction;
a first structure including a channel layer that passes through the stacked structure and a memory pattern between the channel layer and the stacked structure; and
a second structure including an insulating pattern that is formed along a sidewall of the stacked structure and a gate pattern that is formed on a sidewall of the insulating pattern.

2. The semiconductor memory device of claim 1,
wherein the first structure includes a curved portion and a straight portion,
wherein the curved portion contacts the sidewall of the stacked structure, and
wherein the straight portion contacts a sidewall of the second structure.

3. The semiconductor memory device of claim 2, wherein the channel layer has edges that are formed at intersections of the curved portion and the straight portion.

4. The semiconductor memory device of claim 1, wherein the insulating pattern includes at least one of an oxide and a nitride.

5. The semiconductor memory device of claim 1, wherein the insulating pattern is disposed between the stacked structure and the gate pattern and extends between the first structure and the gate pattern.

6. The semiconductor memory device of claim 1, wherein the second structure has a linear shape extending in a horizontal direction substantially parallel to each of the insulating layers and the conductive layers.

7. The semiconductor memory device of claim 1, wherein the first structure has substantially a semicircular shape.

8. A semiconductor memory device, comprising:
a first stacked structure and a second stacked structure that are spaced apart from each other, each of the first and second stacked structures including conductive layers that are stacked in a vertical direction;
a first structure including a first channel pattern that passes through the conductive layers of the first stacked structure and a first memory pattern between the first channel pattern and the first stacked structure;
a second structure disposed between the first stacked structure and the second stacked structure; and
a third structure including a second channel pattern that passes through the conductive layers of the second stacked structure and a second memory pattern between the second channel pattern and the second stacked structure,
wherein the second structure includes a gate pattern between the first structure and the third structure, and
wherein the second structure includes insulating patterns at opposite sides of the gate pattern.

9. The semiconductor memory device of claim 8, wherein each of the insulating patterns extends to contact the first stacked structure and the first structure or extends to contact the second stacked structure and the third structure.

10. The semiconductor memory device of claim 8,
wherein the first structure comprises:
a first curved portion contacting the first stacked structure; and
a first straight portion contacting one of the insulating patterns, and
wherein the third structure comprises:
a second curved portion contacting the second stacked structure; and
a second straight portion contacting another of the insulating patterns.

11. The semiconductor memory device of claim 8, wherein the first structure and the third structure are substantially symmetrical with respect to the second structure.

12. The semiconductor memory device of claim 8, wherein each of the insulating patterns includes at least one of an oxide and a nitride.

13. The semiconductor memory device of claim 8, wherein the second structure has a linear shape extending in a horizontal direction substantially parallel to each of the conductive layers.

14. The semiconductor memory device of claim 8, wherein each of the first channel pattern and the second channel pattern has an edge adjacent to the gate pattern.

15. A semiconductor memory device, comprising:
a stacked structure including insulating layers and conductive layers that are alternately disposed in a vertical direction;
a first structure including a first channel pattern that passes through the stacked structure and a first memory pattern between the first channel pattern and the stacked structure;
second structures passing through the stacked structure and neighboring each other with the first structure interposed therebetween; and
a third structure facing the first structure between the second structures and including a second channel pattern that passes through the stacked structure and a second memory pattern between the second channel pattern and the stacked structure,
wherein each of the second structures includes an insulating pattern that is formed along a sidewall of the stacked structure, and
wherein each of the second structures includes a gate pattern that is formed on a sidewall of the insulating pattern.

16. The semiconductor memory device of claim 15, wherein:
the first structure includes a first curved portion that contacts the stacked structure;
the third structure includes a second curved portion that contacts the stacked structure; and
each of the second structures includes a third curved portion that is coupled to the first curved portion and the second curved portion and that contacts the first structure and the third structure.

17. The semiconductor memory device of claim 15, wherein each of the second structures has substantially a cylindrical shape.

18. The semiconductor memory device of claim 15, wherein the insulating pattern includes at least one of an oxide and a nitride.
